(19) United States
(12) Patent Application Publication
(10) Pub. No.: US 2013/0020986 A1
(43) Pub. Date: Jan. 24, 2013

(54) SELF-REPLENISHING ENERGY STORAGE DEVICE AND METHOD FOR FOOTWEAR

(71) Applicants: Joseph M. Linzon, Toronto (CA); Alexander X. Lozano, Toronto (CA)

(72) Inventors: Joseph M. Linzon, Toronto (CA); Alexander X. Lozano, Toronto (CA)

(73) Assignee: POWERSOLE, INC., Wilmington, DE (US)

(21) Appl. No.: 13/551,302

(22) Filed: Jul. 17, 2012

Related U.S. Application Data
(60) Provisional application No. 61/572,593, filed on Jul. 19, 2011.

(51) Int. Cl. H02J 7/00; H05K 13/00

(52) U.S. Cl. 320/107; 29/592.1

(57) ABSTRACT

Embodiments of an energy harvesting and storage system for footwear are described herein. In some embodiments, the system includes a charge generator, such as a permanent magnet movable with respect to a conductive coil to induce an electrical potential, and thus an electric current, in the winding, which can be used to store charge in an electrical energy storage device. The electrical energy storage device can be accessed via an electrical energy access port. Electrical charge can be used by an external device, or electrical charge can be provided by an external source of charge. The components of the energy harvesting and storage system can be disposed in, or coupled to, and article of footwear, such that when a user moves while wearing the article of footwear, charge can be generated and stored for subsequent use.

### BACKGROUND

The embodiments described herein relate to a system for harvesting and storing within footwear that can convert energy provided by the swinging movement of a foot into electrical energy and store the energy in addition to energy derived from an external source in the footwear.

Mobile electronic devices such as cellular telephones and music players are becoming very common in everyday life. However, the ability to charge these electronic devices has not kept up with their rapid growth in usage. If a mobile, self-replenishing back-up source of power could be integrated into an object or a device that a user always carries or uses such as, for example, footwear, then the duration and range of use of such electronic devices could be increased dramatically.

### SUMMARY

Embodiments of a system for harvesting and storing energy for footwear are described herein. In some embodiments, the energy harvesting system includes a charge generator, such as a permanent magnet movable with respect to a conductive coil to induce an electrical potential, and thus an electric current, in the winding, which can be used to store charge in an electrical energy storage device in or on the footwear. The electrical energy storage device can be accessed via an electrical energy access port. Electrical charge can be used by an external device, or electrical charge can be provided by an external source of charge. The components of the energy harvesting system can be disposed in, or coupled to, and article of footwear, such that when a user moves while wearing the article of footwear, charge can be generated and stored for subsequent use.

### BRIEF DESCRIPTION OF THE DRAWINGS

FIG. 1 is a schematic illustration of an energy harvesting and storage system associated with an article of footwear, according to an embodiment.

FIG. 2 is a schematic illustration of the charge generator of the system of FIG. 1.

FIG. 3 is a schematic illustration of the electrical energy access port of the system of FIG. 1.

FIG. 4 is a schematic illustration of various components associated with an article of footwear, according to an embodiment.

FIGS. 5A-5C are schematic illustrations of charge generators according to several embodiments.

FIGS. 6A-6C are schematic illustrations of conductive coils for use in charge generators according to several embodiments.

FIGS. 7A-7E are schematic illustrations of magnets for use in charge generators according to several embodiments.

FIGS. 8A-8C are schematic illustrations of energy converters according to several embodiments.

FIG. 9 is a schematic illustration of an alternative embodiment of an energy converter.

FIG. 10 is a flow chart of a method of converting energy from the movement of an article of footwear to stored electrical energy and using the stored electrical energy to charge an electronic device.

FIG. 11 is a flow chart of a method of assembling the components of an energy harvesting system with an article of footwear.

FIGS. 12A and 12B are cross sectional views of an article of footwear incorporating an energy harvesting system according to an embodiment, taken along planes perpendicular to and parallel to the sole of the article of footwear.

FIG. 13 is a schematic illustration of a cavity inside the ground engaging component of an article of footwear configured to house components of an energy harvesting system according to an embodiment.

FIG. 14 is a schematic illustration of the human gait cycle.

### DETAILED DESCRIPTION

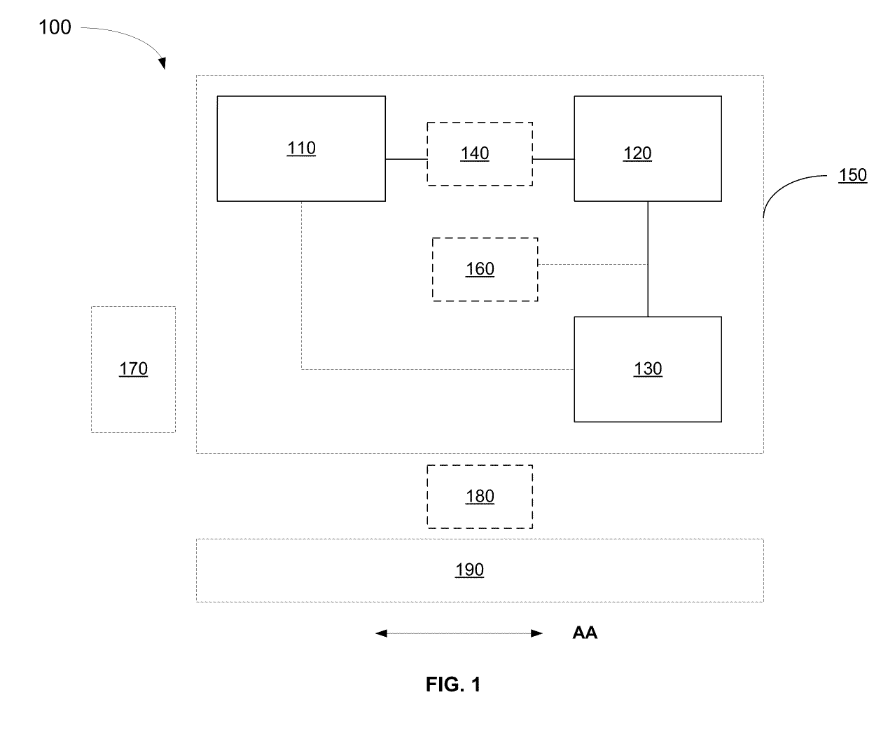

FIG. 1 is a schematic illustration of a system for harvesting and storing energy associated with an article of footwear, according to an embodiment. The energy harvesting and storage system 100 includes a charge generator 110, an electrical energy storage device 120 coupled to the charge generator 110, and an electrical energy access port 130 coupled to the electrical energy storage device 120 (and optionally to the charge generator 110). Optionally (as indicated by dashed lines), system 100 may also include a rectifier (or other electrical energy conditioning component) 140 coupled between the charge generator 110 and the electrical energy storage device 120, a signal generating device 160 coupled to the electrical energy storage device 120 and the electrical energy access port, and a coupler 180. The system 100 may further include an article of footwear 190 in which is disposed, and/or to which are coupled (for example, by coupler 180), the other elements of the system. Further optionally, the system 100 may include a water resistant enclosure 150 to enclose, and protect from exposure to water, some or all of the electrical components of system 100. Further optionally, the system may include an instruction manual 170.

The charge generator 110 may include any one or more suitable mechanisms for converting energy, momentum, and/or force available from the article of footwear 190 (e.g. by movement of a user's foot when wearing the article of footwear 190) into electrical energy. Suitable mechanisms can include a conductive winding and a magnet disposed for movement relative to each other, which causes an electrical current to be induced within the conductive coil due to the phenomenon described in Faraday's law of induction. Other suitable mechanisms include piezoelectric generation mechanisms, hydroelectric generation mechanisms, and pneumatic electrical energy generation mechanisms.

The electrical energy storage device 120 may include any one or more suitable mechanisms for storing electric charge produced by the charge generator 110 or received from other sources, e.g. via electrical energy access port 130, such as electrochemical cells (e.g. secondary, rechargeable batteries), or capacitors. The electrical energy access port 130 provides electrical connectivity between the electrical energy storage device 120 (and optionally the charge generator 110) and any device that uses electrical energy or that provides electrical energy. The electrical energy access port 130 can be of any suitable configuration or format, such as a computer style port (serial port, parallel port, universal serial bus (USB) port) or a household electrical outlet.

In some instances, the electrical energy access port 130 can be electrically connected (wired or wirelessly) to an external power supply device such as for example, an electrical charger, an AC power supply, a DC power supply, a linear regulated power supply, and/or the like. In such instances, the electrical energy access port 130 can facilitate the flow of electrical energy from the external power supply device to the electrical energy storage device 120. This energy can be stored in the electrical energy storage device 120 and can be used to charge and electronic device at a subsequent time.

The electrical current generated by the charge generator 110 (e.g. due to the movement of the user's foot) may be alternating current (AC), e.g. direct current of varying voltage that periodically reverses direction or polarity (e.g. in different portions of the gait cycle of the user). In some embodiments, the system can include a step-up and/or step-down transformer that can change the voltage of the alternating current (AC) output from the charge generator 110 to either increase (“step up,” or amplify) or decrease (“step down,” or attenuate) before rectification and charging of the electrical energy storage device 120. Such step-up/step-down transformers can be, for example, based on solid state electronics and miniaturized for easy incorporation into the system 100. The transformer could also take the form of a Direct Current (DC) to DC power conditioner. Rectifier 140 can be used to convert the AC output of the charge generator 110 (or step-up/step-down transformer) to direct current (DC), which does not change polarity and flows in only one direction. The rectifier 140 may include any suitable device for conditioning the electrical current from the charge generator 110, such as vacuum tube diodes, mercury-arc valves, solid-state diodes, silicon-controlled rectifiers or any other silicon-based semiconductor switches. In some embodiments, the rectifier 140 can be followed by a filter, comprising of one or more capacitors, resistors, and sometimes inductors, to filter out (smoothen) most of the pulsation that is generally present in the DC output of the rectifier 140. In other embodiments, either the rectifier 140 (or the filter) is electrically coupled to an amplifier that can modulate (i.e. amplify or attenuate) the current output of the rectifier 140. In such embodiments, the amplifier can be electrically coupled to the electrical energy storage device 120.

As noted above, the system 100 may include a signal generating device 160, which can be, for example, an accelerometer, a pedometer, a global positioning system (GPS) tracking device, or any other device that generates a signal and requires electrical energy to operate. The signal generator 160 may, for example, track movement or energy data in the article of footwear 190 and send the data either wirelessly or through a wired connection to any device such as, for example, a personal music player, a phone, a computer, and so forth in order to track information such as, for example, energy (or calories) consumed in walking/running, distance travelled by the article of footwear 190, previous location(s) of the article of footwear 190, speed of walking or running, running style of the user of the article of footwear, and/or the like.

As noted above, some or all of the electrical components of the energy harvesting and storage system 100 can be placed inside a water resistant enclosure 150 in order to prevent damage that can arise from article of footwear being exposed to moisture, e.g. from the user using the article of footwear in the rain or stepping into a puddle of water, perspiration from the user's foot, etc. The water resistant enclosure 150 can be made of any suitable material that is resistant to moisture such as, for example, rubber, polyvinyl chloride, polyurethane, silicone elastomer, or fluoropolymers.

The article of footwear 190 can be, for example, athletic, hiking, training, or casual footwear that can consist of a ground engaging unit (i.e. a sole), a cavity which can house the energy harvesting and storage system 100, a retainer and a cover as will described in greater detail herein. Additionally, in some embodiments, a mechanical coupler 180 can be used to couple one or more components of the system 100 to the article of footwear 190. The various components of the system 100 are not limited to being inside the cavity of an article of footwear 190. In some embodiments, one or more components of the system 100 can be housed inside the cavity of an article of footwear 190 while the other components of can be located outside the cavity of the article of footwear 190.

The instruction manual 170 can contain information associated with the specifications of the different electrical and electro-magnetic components of the energy harvesting and storage system 100, such as information associated with the principle of operation of the system 100 and Faraday's Law of induction, and/or instructions associated with installing components of the system into an article of footwear 190. The instruction manual 170 can be included in any suitable format, such as a printed paper manual, a compact disc (CD), a video compact disc (VCD), a digital versatile device (DVD), a USB Flash Drive, or an electronic file downloadable from the Internet.

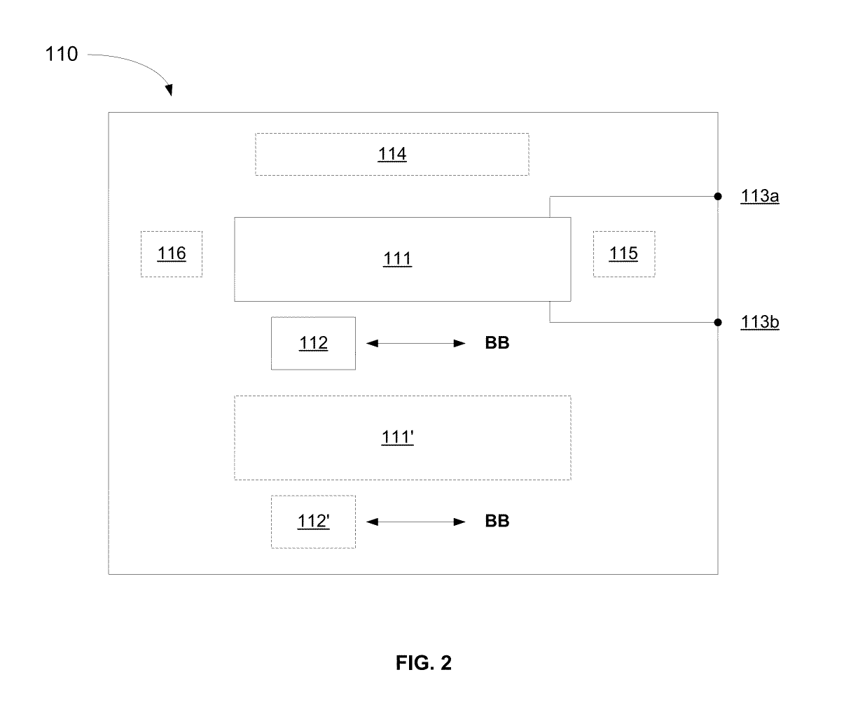

FIG. 2 is a schematic illustration of the charge generator of the system of FIG. 1. The charge generator 110 can include a conductive coil 111, a magnet 112 disposed in close proximity of the conductive coil 111, and electrical wiring 113a and 113b that connects the charge generator 110 to the other electrical components of the energy harvesting and storage system 100. Optionally (as indicated by dashed lines) the charge generator can also include an enclosure (for the conductive coil) 114, energy converters 115 and 116 disposed at the end of the conductive coil 111 that facilitates the back and forth movement of the magnet 112 with respect to the conductive coil 111, and additional conductive coil(s) 111′ and magnet(s) 112′. BB denotes the direction of the movement of the magnet(s) 112 and/or conductive coil(s) 111 that can occur due to the swinging motion of a foot that takes place during different portions of the users gait cycle. The charge generator 110 converts kinetic energy from the swinging motion of the foot during the gait cycle to electrical energy that can be stored in the electrical energy storage device 120 for use at a subsequent time. The conductive coil 111 can consist of any conductive wire wrapped, for example, in a helical pattern around the central axis of the enclosure 114. Examples of conductive materials can include, but is not limited to, copper, aluminum, gold, platinum, molybdenum, and alloys thereof. Some of the parameters that can be manipulated to fabricate conductive coils of varying strengths can include, but are not limited to, the gauge of the wire, interleaving of wires of different gauge sizes, wrapping direction (e.g. the coil can be always wrapped in a clockwise direction or it can alternate between clockwise and anti-clockwise direction between neighboring turns), and wrapping pattern (e.g. uniform wrapping density or wrapping with varying density of the wire), as will be described in greater detail herein.

The magnet(s) 112 are permanent magnets that can be made of any number of “hard” ferromagnetic materials such as alnico, ferrite, or neodymium iron boron, that are subjected to special processing in a powerful magnetic field during manufacture, to align their internal microcrystalline structure, thus rendering them very hard to demagnetize at a subsequent time. The magnet(s) 112 and/or 112′ are disposed for movement relative to the conductive coil(s) 111 and/or 111′ in each of a first direction and a second, opposite direction. The movement of the magnet(s) 112 and/or 112′ in the first direction generates an electrical potential of a first polarity, and the movement of the magnet(s) 112 and/or 112′ in the second direction generates an electrical potential of a second, and opposite polarity. The magnet(s) 112 and/or 112′ can have a variety of cross-sections such as, for example, rectangular, square, circular or trapezoidal cross-section. The magnet(s) 112 and/or 112′ can also have a variety of configurations such as, for example, a single magnet with a rectangular cross-section, a single magnet with a circular cross-section, double magnets with circular cross-section, double magnets with rectangular cross-section, double magnets including one with circular cross-section and the other with rectangular cross-section, or any other combination of these configurations. The enclosure 114 can have any suitable configuration, such as, for example, cylindrical, or rectangular, square, or trapezoidal cross-section, or torroidal.

The electrical wiring 113a and 113b can electrically couple the two terminals of the conductive coil 111 to external electronic circuitry such as a rectifier 140 or directly to the electrical energy storage device 120. The energy converters 115 and 116 are disposed in operative relationship with the magnet 111 and can convert the kinetic energy of the moving magnet 112 (and/or 112′) to potential energy stored in the energy converters 115 and 116, and can also convert the stored potential energy back to the kinetic energy of the moving magnet 112 (and/or 112′). In some instances, the energy converters 115 and 116 can be a resilient member such as a coiled spring. In such instances, the energy converters 115 and 116: a) absorbs the kinetic energy of the moving magnet 112 as it approaches one end of the enclosure 114; b) stores the absorbed kinetic energy as potential energy,; and c) releases at least a portion of the stored potential energy as kinetic energy of the moving magnet 112 as the magnet 112 starts to move in the opposite direction.

In other instances, the energy converters 115 and 116 can be a second set of magnet(s) being disposed and oriented so that the polarity of the energy converter(s) is opposite to that of the moving magnet 112. In such instances, the energy converters 115 and 116 decelerate the moving magnet 112 via magnetic repulsion as the moving magnet 112 approaches one end of the enclosure 114, stops the magnet 112, and subsequently repels the magnet 112 in the opposite direction. In such instances, the kinetic energy of the moving magnet 112 is initially stored as potential energy in the energy converters 115 and 116, before being transferred back to the magnet 112 as kinetic energy that drives the motion of the magnet 112 in the opposite direction.

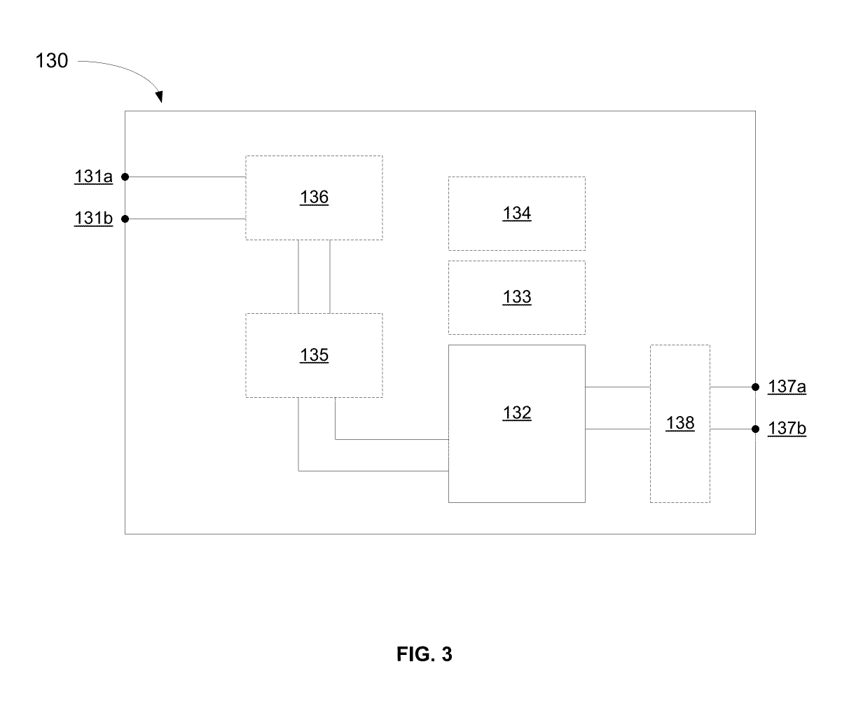

FIG. 3 is a schematic illustration of the different components associated with the electrical energy access port, according to an embodiment. The electrical energy access port 130 can be mounted to the article of footwear 190 and can be configured to be accessible from either the exterior or the interior of the article of footwear 190. The electrical energy access port 130 can be electrically connected (wired or wirelessly) to various components of the energy harvesting and storage system 100 including being connected to the electrical energy storage device 120 to deliver electrical energy from the electrical energy storage device 120 to an external device that uses electrical energy. The electrical energy access port 130 can include a first group of electrical wiring 131a and 131b, an electrical coupler 132, a second group of electrical wiring 137a and 137b, and, optionally a mechanical coupler 133, a wireless coupler 134, a step-up/step-down transformer 135, and/or a rectifier 136. In some instances, the electrical energy access port 130 can deliver electrical energy from the electrical energy storage device 120 to a device that uses electrical energy. In other instances, the electrical energy access port 130 can receive electrical energy from an external power supply device and deliver it to the electrical energy storage device 120.

Optionally, the electrical energy access port 130 can include regulating electronics 138, which can convert the output from the electrical energy storage device 120 to a suitable voltage and/or amperage for use by the device coupled to the electrical energy access port 130. The regulating electronics can also convert the output from an external energy source coupled to the electrical energy access port to a voltage and/or amperage suitable for use by the electrical energy storage device.

The electrical coupler 132 can electrically couple the electrical energy access port 130 to an input port of any device that uses electrical energy or an output port of any external power supply device. The electrical coupler 132 can be electrical connections associated with, for example, a USB female port, a serial port, a parallel port, and/or the like. The electrical wiring 137a and 137b can electrically couple the electrical energy access port 130 to the input port of an external electrical device or the output port of an external power supply source during wired connections. The mechanical coupler 133 can mechanically couple the electrical energy access port 130 to an input port of any device that uses electrical energy or the output port of any external power supply device. The mechanical coupler 133 can be used for the wired connection of the energy harvesting and storage system 100 to an external electronic device or an external power supply device. The mechanical coupler 133 can be the mechanical connections such as adapters associated with, for example, a USB female port, a serial port, a parallel port, and/or the like. The wireless coupler 134 can wirelessly couple the electrical energy access port 130 to the wireless input port of any device that consumes electrical energy or the wireless output port of any external wireless power supply device. In instances when the energy harvesting and storage system 100 is charging an external electrical device wirelessly, the wireless coupler 134 can also include the electronic circuitry required to implement a wireless transmitter. The wireless coupler 134 can be used to couple to the wireless port of an external electrical device by, for example, electromagnetic induction such as magnetic coupling, electrostatic induction such as capacitive coupling, electrodynamic induction such as inductive coupling, microwave energy transmission, wireless antennas such as WiFi antennas, and/or the like. In instances when the electrical energy storage device 120 is being charged by an external power supply device wirelessly, the wireless coupler 134 can also include the electronic circuitry required to implement a wireless receiver.

The rectifier 136 can be used to convert the alternating current (AC) delivered from an external power supply device such as, for example, a home electrical outlet or an AC power supply source to direct current (DC) during charging of the electrical energy storage device 120 from an external power supply source. The rectifier 136 may include any suitable device for conditioning the electrical current from the AC power supply source, such as vacuum tube diodes, mercury-arc valves, solid-state diodes, silicon-controlled rectifiers or any other silicon-based semiconductor switches. In some instances, the rectifier 136 can also be electrically coupled to a step-up/step-down transformer 135. The step-up/step-down transformer 135 can enable an alternating current (AC) voltage from an external power supply source to be “stepped up” (amplification) or “stepped down” (attenuation) before rectification and charging of the electrical energy storage device 120 from an external power supply device. The electrical wiring 131a and 131b can electrically couple the electrical energy access port 130 to the electrical energy storage device 120.

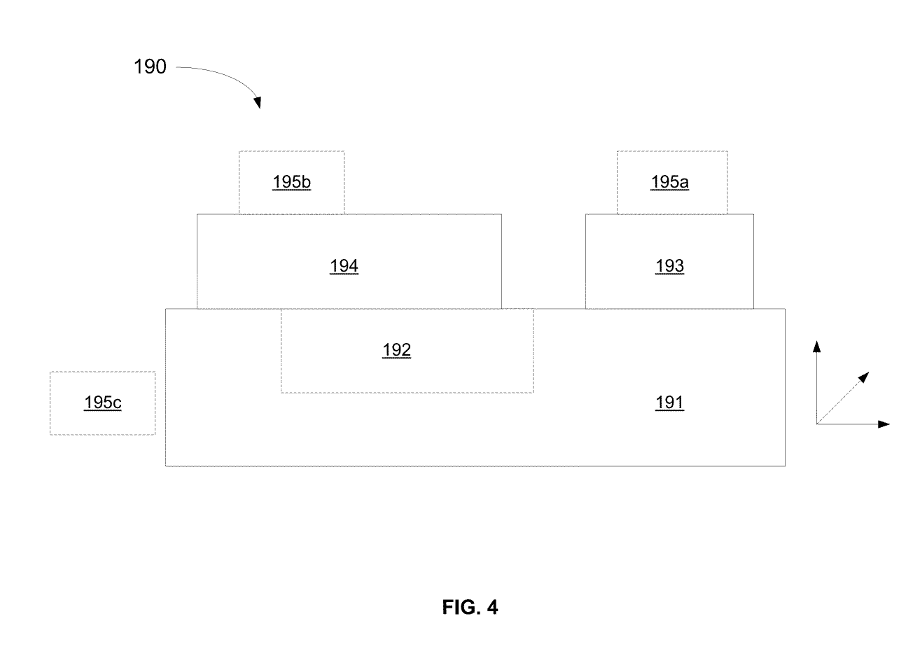

FIG. 4 is a schematic illustration of the different components associated with an article of footwear, according to an embodiment. The article of footwear 190 can be, for example, athletic, hiking, training, or casual footwear that can include a ground engaging unit 191, a retainer 193, a cover 194, and, optionally, a cavity 192, and/or one or more couplers 195a, 195b and 196c. The ground engaging unit 191 can be located on the bottom of article of footwear 190 and is the part that is intended to come in repeated contact with the ground (e.g., the sole). The ground engaging unit 191 can be made from, for example, plant fibers, leather, wood, rubber, synthetics, plastic, and various combinations of these materials. In some instances, the ground engaging unit 191 can be formed of a single material in a single layer. In other instances, the ground engaging unit 191 can be complex and can be formed of multiple structures or layers and materials.

The ground engaging unit 191 can be used to house one or multiple components of the energy harvesting and storage system 100 such as, for example, the charge generator 110. In some instances, the magnet 112 of the charge generator 110 can be disposed for movement relative to the conductive coil 111 in response to the movement of the article of footwear 190 in a direction approximately parallel to the ground engaging unit 191. Additionally, the ground engaging unit 191 can also have a longitudinal axis wherein the magnet 112 of the charge generator 110 can be disposed for movement relative to the conductive coil 111 in response to the movement of the article of footwear 190 in a direction approximately parallel to the longitudinal axis of the ground engaging unit 191.

The cavity 192 can be used to house the one or multiple components of the energy harvesting and storage system 100. In some instances, the cavity 192 can be formed by the manufacturer of the article of footwear 190 during the manufacturing process. In other instances, the cavity 192 can be created by an end user when retrofitting an existing article of footwear 190 with an energy harvesting and storage system kit according to instructions provided in the instruction manual 170. In some instances, the cavity can formed as a single compartment that can house all of the components of the system 100. In other instances, the cavity 192 can be formed as multiple compartments, each configured to house an individual component of the system 100, and can be connected by channels that can house the electrical wiring that electrical couples the components of the energy harvesting system 100.

The retainer 193 may be located on the front portion of the article of footwear 190 and can be used to retain the article of footwear 190 on a user's foot during use. In some embodiments, the retainer 193 can be used to house one or multiple components of the energy harvesting and storage system 100 such as, for example, the rectifier 140 or the electrical energy storage device 120. The cover 194 can consist of the upper portion of the article of footwear 190 that can cover and protect the user's foot. The cover 194 can be made from, for example, leather, rubber, synthetics, plastic, or various combinations of these materials. In some embodiments, the cover 194 can also be used to house one or multiple components of the system 100 such as, for example, the rectifier 140 or the electrical energy storage device 120. Any one or more of the couplers 195a, 195b, and/or 195c can couple one or more components of the system 100 to the ground engaging component 191.

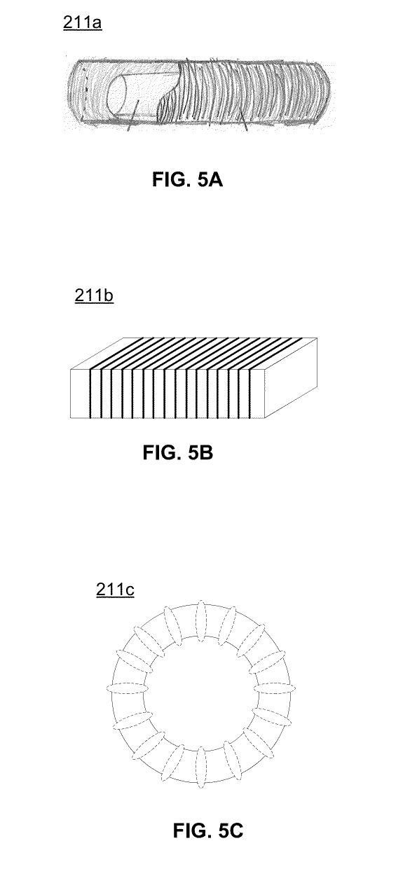

FIGS. 5A-5C are schematic illustrations of charge generators according to several embodiments. In some embodiments, the charge generator can include a conductive coil wrapped in a helical pattern around an enclosure and with a magnet disposed inside the enclosure, for example as shown in FIG. 5A, for reciprocating movement within the enclosure relative to the conductive coil. The conductive coil enclosure can be of any suitable configuration. For example, the enclosure can be any elongate shape of approximately constant cross-section, whether circular, elliptical, or polygonal (triangular, rectangular, pentagonal, etc.), and which may be referred to herein as “cylindrical.” As discussed above, the enclosure can be of any desired cross-sectional shape, such as the circular cross-section shown for the charge generator 211a in FIG. 5A or the rectangular cross-section for the charge generator 211b shown in FIG. 5B. Correspondingly, the magnet can be of any suitable shape to reciprocate freely within the enclosure, such as the cylindrical shape shown in FIG. 5A, or a spherical shape to conform to the circular cross section of the enclosure shown in FIG. 5A. Alternatively, the magnet may have a rectangular cross-section to conform with the cross-section of the enclosure shown in FIG. 5B. Preferably, the cross-section of the magnet is somewhat smaller than that of the enclosure to provide clearance between the magnet and enclosure and thus minimize energy losses due to friction.

The enclosure, and thus the magnet path, need not be linear, as shown in FIGS. 5A and 5B. Alternatively, the enclosure may be arcuate, though still require reciprocating motion of the magnet. Further alternatively, the enclosure may define a continuous path for the magnet, such as a circular, elliptical, or other closed shape. For example, as shown in FIG. 5C for the charge generator 211c, the enclosure can be torroidal. An enclosure defined a continuous, closed path for the magnet may allow for harvesting energy from the motion of the foot in multiple directions during the user's gait cycle. This can lead to increased efficiency in electrical energy generation. This configuration can also avoid potential losses associated with the magnet reversing direction (e.g., impacting the end of a linear enclosure) or the need for energy converters.

The enclosure is not required for the charge generator to generate electric potential due to the changing magnetic fields created by moving the magnet, but can just function as a form around which the conductive windings can be wound. Although in the embodiment illustrated in FIGS. 5A-5C the magnet associated with the charge generator is disposed inside the enclosure, in alternative embodiments the magnet can be disposed outside the enclosure but within close proximity to the conductive coil.

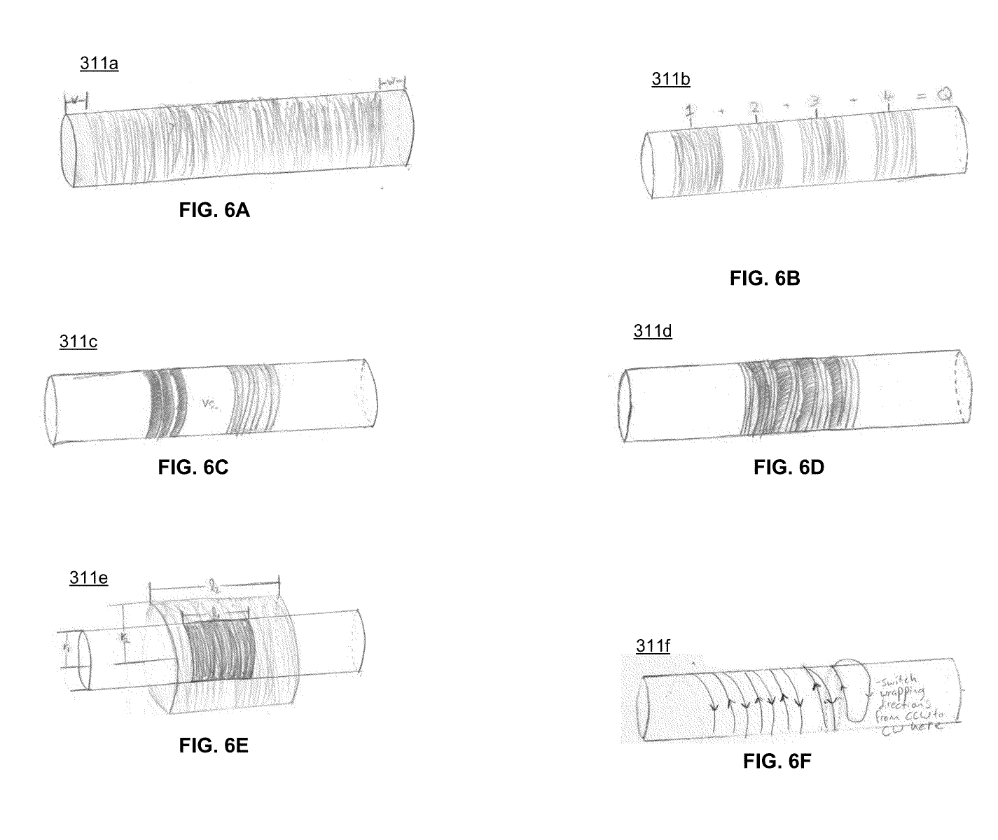

FIGS. 6A-6F are schematic illustrations of conductive coils suitable for use in charge generators according to several embodiments. In some embodiments, such as the one shown in FIG. 6A, the conductive coil 311 a can include a single coil with multiple turns of wire of uniform diameter wrapped with uniform inter-turn spacing around an enclosure. In other embodiments, such as those shown in FIGS. 6B and 6C, the conductive coil (311b and 311c, respectively) can include multiple coils wrapped around an enclosure. In such embodiments, parameters such as wire diameter, number of turns, and inter-turn spacing may or may not be varied between coils. In other embodiments, such as that shown in FIG. 6D, the conductive coil 311d can include two or more coils consisting of wires with varying diameters that are interleaved. In this configuration, the thicker wire(s) can facilitate the passage of electric current (once the charge generator 110 is connected to via the electrical wiring to the other electrical elements in the system 100), since thicker wires have lower resistance. The thinner wires can increase the total number of turns for the coil and hence can increase the electrical potential created by the moving magnet. In other embodiments, such as the one shown in FIG. 6E, the conductive coil 311e can include an additional layer of conductive coil wrapped around an inner layer. The second, outer coil can surround the first, inner coil that is directly wrapped around the enclosure and can be used to capture portions of the changing magnetic flux that the inner conductive coil cannot capture. In yet other embodiments, such as that shown in FIG. 6F, the conductive coil 311f can include wires wrapped in alternating directions between neighboring turns. This configuration of the conductive coil 311f can increase the efficiency of generating electric potential from the changing magnetic flux as magnet moves back and forth in opposite directions relative to the conductive coil.

For any of the coil configurations described above, the design can be guided by the considerations that the strength of the electrical potential created by the moving magnet is proportional to the number of turns of the conduction coil (which favors the use wires of smaller diameter to increase the number of turns around an enclosure of limited size) and the resistance of the coil (and thus losses to ohmic heating) increases with decreased diameter of the conductive wire.

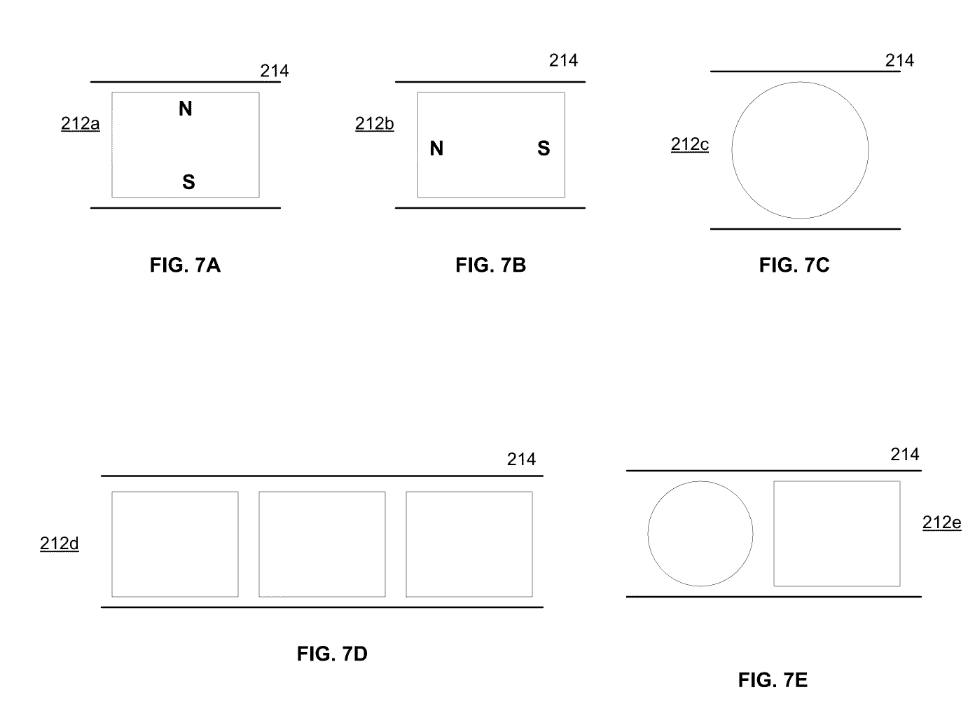

FIGS. 7A-7E are schematic illustrations of magnet shapes and orientations suitable for use in charge generators according to several embodiments. As noted above, each magnet can be made of any one of a number of “hard” ferromagnetic materials, such as Alnico, ferrite, samarium cobolt, or neodymium iron boron. The magnet(s) can have a variety of cross-sections, conformations, and polarities, as shown in FIGS. 7A-7E. In some embodiments, such as that shown in FIG. 7A, a magnet can be a cubic magnet 212a, i.e. with a rectangular cross-section, and with the magnetic axis (between the north and south poles of the magnet) transverse to the direction of motion of the magnet in the enclosure 211. In other embodiments, such as that shown in FIG. 7B, the magnet can be a single cubic magnet 212b with a rectangular cross-section with the magnetic axis parallel to the direction of motion of the magnet in the enclosure 211. In yet other embodiments, the magnet can be a single spherical magnet 212c, i.e., with a circular cross-section, as shown in FIG. 7C. In such embodiments, the orientation of the magnetic axis relative to the direction of motion of the magnet can change as the magnet moves (rolls) through the enclosure, which may not be desirable. In other embodiments, multiple magnets may be disposed in the enclosure for movement relative to the conductive coil. In such embodiments, the magnets may be physically connected to one another (via any suitable mechanism, not shown) or may be separate. For example, FIG. 7D shows an embodiment in which three separate, cubic magnets 212d, with a rectangular cross-section. In other embodiments, multiple magnets having different shapes can be disposed in the enclosure, for example a spherical magnet with a circular cross-section and a cubic magnet with a rectangular cross-section, as shown in FIG. 7E. In all embodiments of the energy harvesting and storage system 100, the magnet(s) are disposed for movement relative to the conductive coil in each of a first direction and a second, opposite direction. The movement of the magnet(s) in the first direction can generate an electrical potential of a first polarity in the conductive coil, and the movement of the magnet(s) in the second direction can generate an electrical potential of a second, and opposite polarity in the conductive coil.

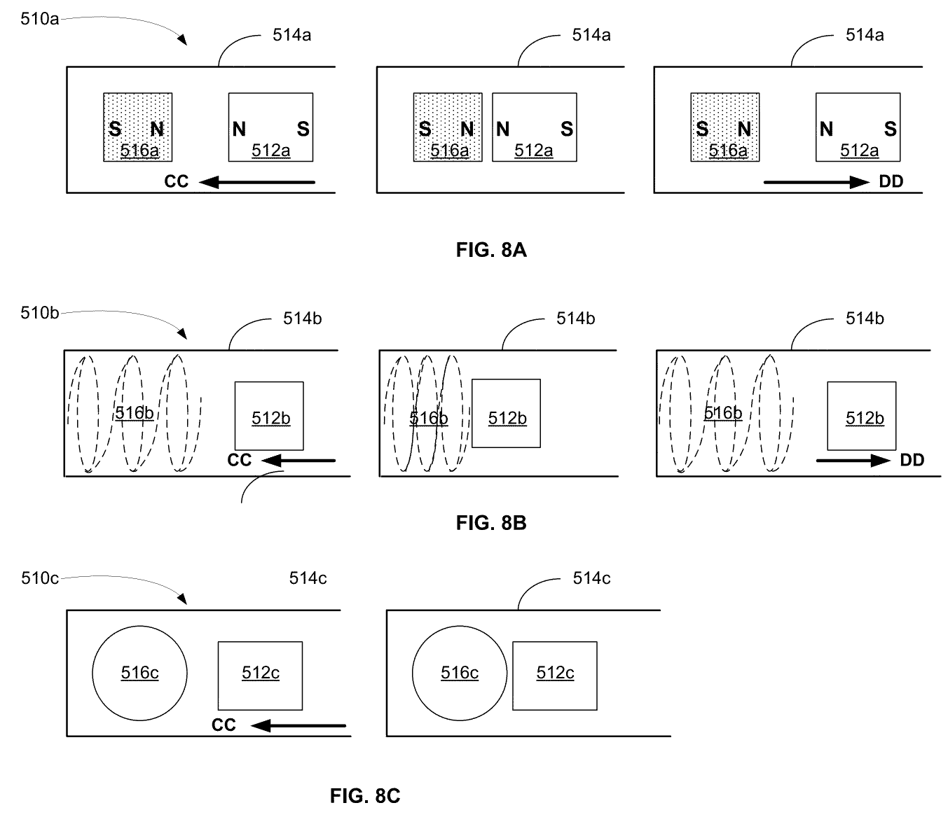

FIGS. 8A-8C are schematic illustrations of several embodiments of energy converters. Each energy converter functions to absorb and store kinetic energy of the moving magnet and then to supply the stored energy to the magnet, at an end of the magnet's path of travel through the conductive coil. This allows the capture of energy that would otherwise be lost to friction heat as the magnet impacts the end of the enclosure.

In one embodiment, such as the one shown in FIG. 8A, the energy converter can include a magnet 516a disposed at one end of enclosure 517a. The magnet 516a can be coupled to enclosure 517a via any suitable mechanism. Magnet 516a is oriented so that its polarity is opposite to that of magnet 512a, i.e. so that like magnetic poles face each other. This creates magnetic repulsion forces which increase as magnet 512 approaches magnet 516a, as represented by arrow CC. This magnetic repulsion force initially retards or decelerates magnet 512a, and can bring magnet 512a to rest, and then can accelerate magnet 512a away from magnet 516a. Thus, the kinetic energy of the magnet 512a (that is in motion along the direction represented by CC) is initially stored as potential energy in the magnetic fields of magnets 516a and 512a, and then transferred back to the magnet 512a as kinetic energy that drives the motion of the magnet 512a in the opposite direction (DD).

In an alternative embodiment, the energy converter can include resilient member, such as a coiled compression spring, which can absorb the kinetic energy of the moving magnet thereby stopping the magnet (from motion to rest), and initiating or supplementing acceleration of the magnet in the opposite direction by transferring the stored potential energy back to kinetic energy of the moving magnet. FIG. 8B illustrates an embodiment of an energy converter 516b based on a coiled compression spring. The spring can be attached to one end of the enclosure 514b. The energy converter 516b can be made of suitable material, preferably not ferromagnetic (to avoid any attractive force between the magnet and the spring), such as, phosphor bronze, titanium, beryllium copper, or aluminum. CC represents the initial direction of motion of the magnet 512b. When the magnet 512b is approaching the end of the enclosure 514b, the energy converter 516b is in an uncompressed state. As the magnet 512b nears the end of the enclosure 514b, it makes contact with the energy converter 516b. The magnet compresses the energy converter 516b, transforming the kinetic energy of the moving magnet 512b to potential energy stored in the spring. After magnet 512b is brought to rest, the spring can transfer its potential energy back to the magnet 512b as kinetic energy, with the magnet 512b moving in the opposite direction as denoted by the arrow DD.

FIG. 8C schematically illustrates another embodiment of an energy converter 516c, which can be any suitable mechanism for converting kinetic energy from the magnet 512c into stored energy and returning the stored energy to the magnet as kinetic energy, or converting the energy into electrical energy. The energy converter can be implemented via a variety of mechanisms such as, for example, pneumatic energy conversion, hydraulic energy conversion, electromagnetic energy conversion, resilient shock absorbers, and so forth.

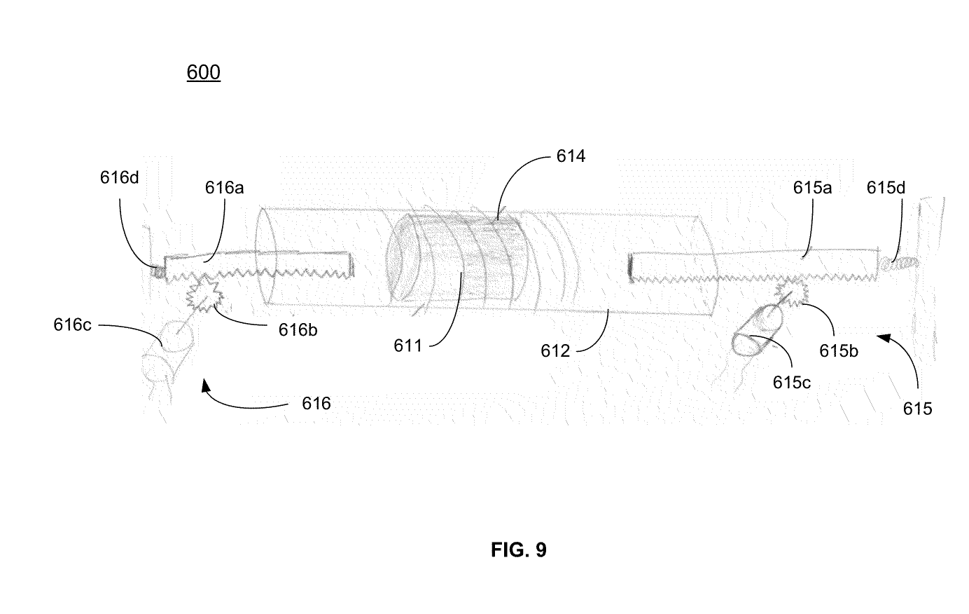

FIG. 9 is a schematic illustration of another alternative embodiment of an energy converter, which can convert kinetic energy of the magnet into electrical energy. The system 600 can include a conductive coil 611 wrapped around an enclosure 614 within which is disposed a magnet 612. The system 600 can include energy converters 615 and 616 at each end of the enclosure 614. The energy converters 615 and 616 can be based on, for example, a rack and pinion mechanism which can include a rack 615a or 616a, a pinion 615b or 616b, an electric generator 615c or 616c, and a coil spring 615d or 616d. In such embodiments, as the moving magnet 612 nears the end of enclosure 614, it can strike the energy converter (615 or 616) at that end of the enclosure 614. Upon impact, the kinetic energy of the magnet 612 can be transferred to the rack (615a or 616a ), to the pinion (615b or 616b ) and then to the electric generator (615c or 616c ), which can generate electrical energy. The electrical energy generated by the electric generator can be stored in, for example, the electric energy storage device (not shown in this embodiment).

The coiled compression springs 615d (or 616d ) attached to the rack 615a (or 616a ) can be compressed as the magnet 612 displaces the rack 615a (or 616a ). In turn, after the magnet 612 has come to rest, the coiled compression springs 615d (or 616d ) can push back against the rack 615a (or 616a ) to allow the potential energy stored in the compressed spring 615d (or 616d ) to be converted back into the kinetic energy of the magnet 614 (via the rack 615a or 616a ), as the magnet 614 is urged back into motion in the opposite direction. The reverse motion of the rack 615a (or 616a ) can also actuate the electric generator 615c (or 616c ) (via pinion 615b or 616c ) to generate more electric energy. Thus, such embodiments of the energy converter 615 and/or 616 can make use of the coiled spring based energy converter mechanism 516c described in FIG. 8B.

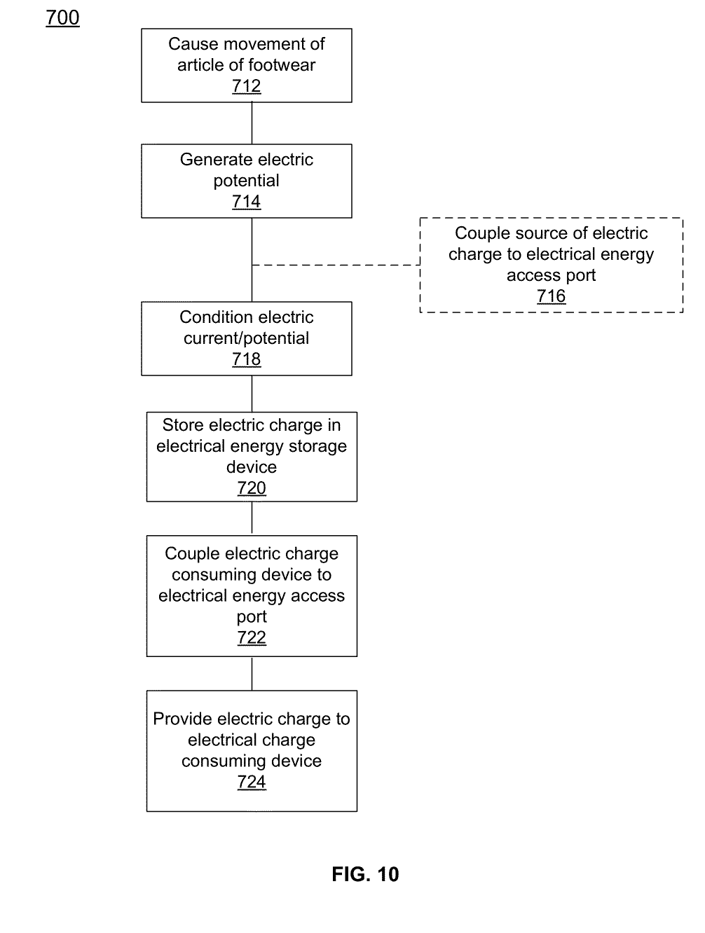

FIG. 10 is a flow chart of a method of converting energy from the movement of an article of footwear to stored electrical energy and using the stored electrical energy to charge an electronic device. The method 700 includes causing movement of an article of footwear, at 712. As described above, the movement of the article of footwear can be associated with the different kinds of foot movements that can occur during a user's normal gait cycle such as, for example, the heel strike, the mid stance, and the swing. An electric potential can be generated as a result of the movement of the article of footwear, at 714, such as by movement of the article of footwear causing the magnet to move relative to the conductive coil, generating a changing magnetic flux that interacts with the conductive coil to induce an electromotive force or electric potential in the conductive coil.

The electric potential generated at 716 can be conditioned, at 718. As discussed above, the electric current/potential generated by the charge generator may be alternating current/potential (AC). The electric current/potential can be conditioned by using a device such as a rectifier to convert the AC output of the charge generator to direct current (DC), which does not change polarity, and flows in only one direction. The conditioned charge can be stored in the electrical energy storage device, at 720.

An electric charge consuming device may be coupled to the electrical energy access ports, at 722. As discussed above, the coupling can take place though wired connections or wireless connections. Electric charge can then be provided to the coupled electric charge consuming device, at 724.

Optionally (as indicated by dashed lines), method 700 may also include coupling a source of electrical charge to the electrical energy access port, at 716, to provide charge to the electrical energy storage device, which can be used to charge an electronic device at a subsequent time.

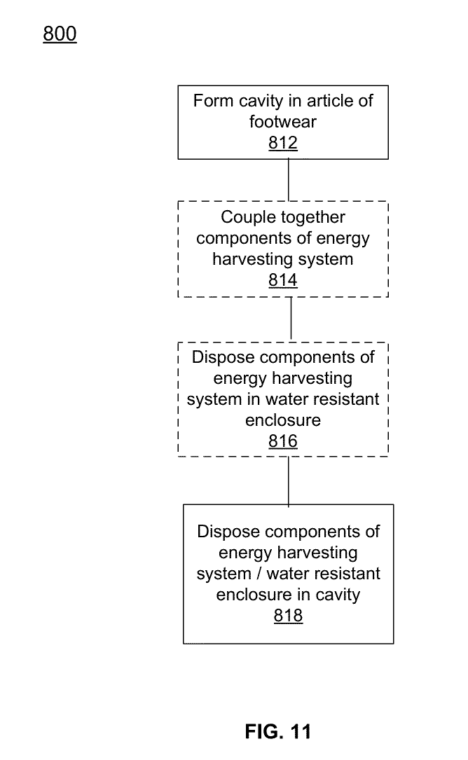

FIG. 11 is a flow chart of a method of assembling the components of an energy harvesting and storage system with an article of footwear. The method 800 includes forming a cavity in an article of footwear, at 812. The cavity can be formed during the process of manufacturing the article of footwear, i.e. by the footwear manufacturer. Alternatively, the cavity can be formed by an end user of the article of footwear, for example to retrofit an existing article of footwear with an energy harvesting and storage system, such as by following instructions provided in an instruction manual.

Optionally (as indicated by dashed lines), method 800 may also include coupling together components of the system, at 814. In some embodiment, the system can be provided in the form of a kit with its individual components unconnected (or uncoupled), and the user can couple the components of the kit according to instructions that can be provided in an instruction manual. Further optionally, some or all of the components of the system can be disposed in a water resistant enclosure, at 816. As noted above, some or all of the components of the system can be disposed in a water resistant enclosure in order to avoid damage from exposure to moisture. The water resistant enclosure can be in the form of a single unit that can hold all the components, or may be formed multiple parts, with each part designed to hold a specific component of the system. Alternatively, the cavity in the article of footwear may be configured to be sufficiently water resistant that a separate water resistant enclosure is not required.

Finally, the components of the system, and optionally the water resistant enclosure, can be disposed in the cavity of, or otherwise coupled to, the article of footwear, at 818. This step may include sealing the cavity so that the components of the system are secured within the cavity.

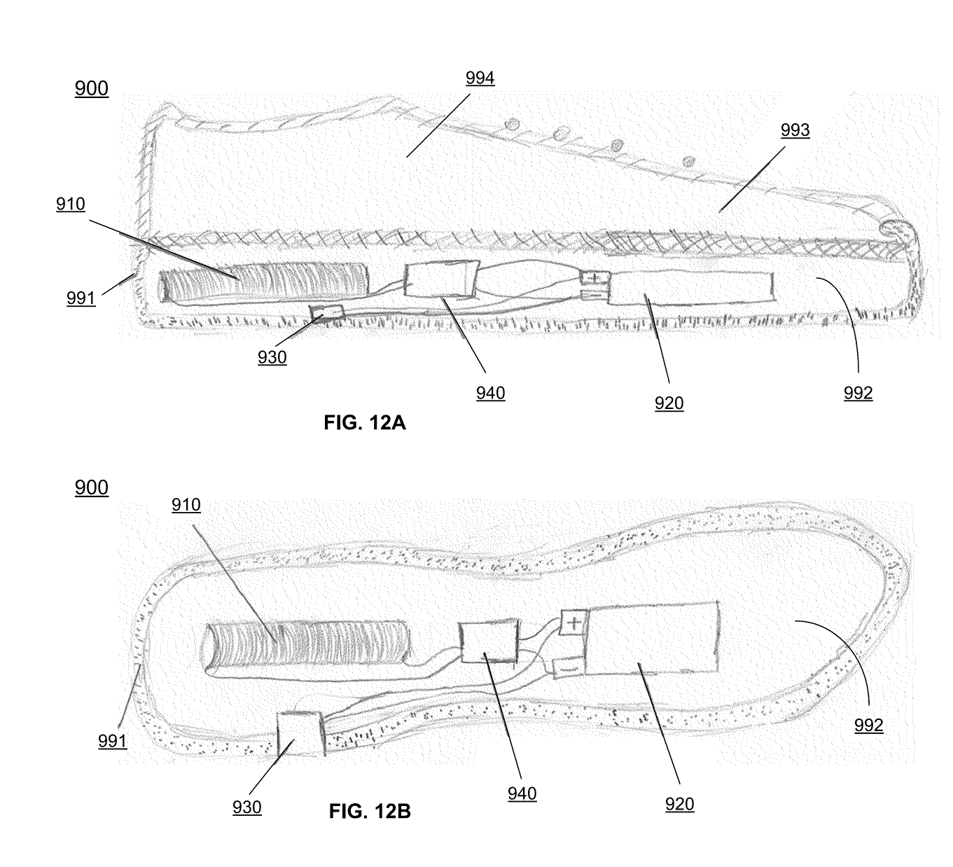

FIGS. 12A and 12B are cross sectional views of an exemplary article of footwear incorporating an energy harvesting and storage system according to an embodiment, taken along planes approximately perpendicular to (FIG. 12A) and parallel to (FIG. 12B) the sole of the article of footwear. The article of footwear includes a ground engaging unit 991 (i.e. the sole) with a single cavity 992 within which are disposed all the components of the system. The system includes a charge generator 910 which includes a single wire helically wrapped, with uniform inter-turn spacing, around a cylindrical enclosure and with a magnet (not shown) disposed inside the enclosure. The charge generator 910 is electrically coupled to a rectifier 940, which can convert the AC current from the charge generator 910 to DC current. The rectifier 940 may also include a filter to filter out, or smooth, some or all of the pulsation that is generally present in the DC output of the rectifier 940. The rectifier 940 can also be electrically coupled to an amplifier that can modulate (i.e. amplify or attenuate) the current output of the rectifier 940. The output of the rectifier 940 (or optional amplifier) is connected to an electrical energy storage device 920, which can include any one or more of the suitable mechanisms described above for storing electric charge produced by the charge generator 910. The electrical energy storage device 920 is connected via electrical wiring to the electrical energy access port 930, which can be of any of the suitable configurations or formats described above

The article of footwear incorporating the system 900 also includes a retainer 993 on the front of the footwear and a cover 994 (or protector) on the top and back of the footwear. The retainer 993 is located in the front part of the article of footwear and is used to retain the article of footwear on the foot during the users gait cycle. The cover 994 is essentially the upper portion of the article of footwear 190 that can cover and protect the user's foot. As noted herein, the cover 994 can be made from, for example, leather, rubber, synthetics, plastic, or various combinations of these materials. In some embodiments, one or multiple components of the system 100 can be disposed in the cover retainer 993 or cover 994 such as, for example, the rectifier 140 or the electrical energy storage device 120.

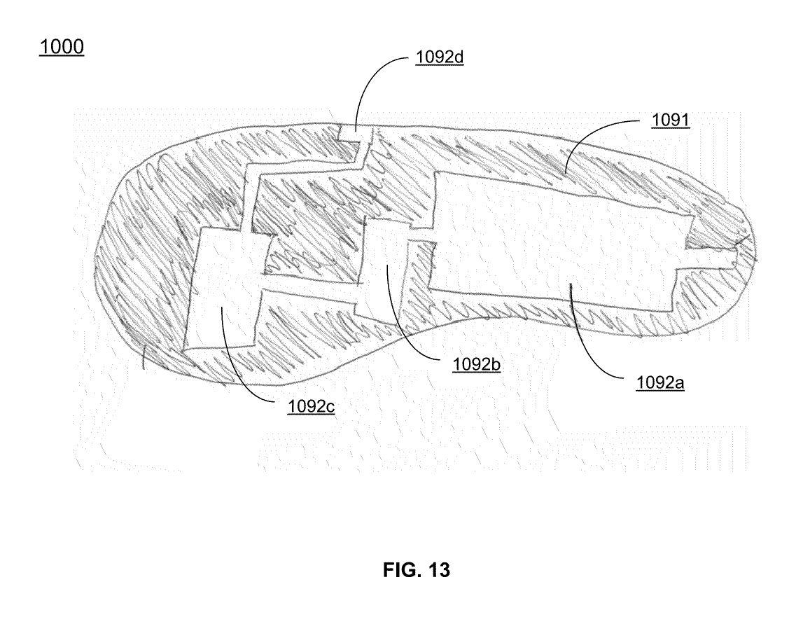

FIG. 13 is a schematic illustration of a cavity inside the ground engaging component of an article of footwear configured to house components of an energy harvesting and storage system according to an embodiment. The cavity 1000 is bounded by the ground engaging component 1091 and consists of individual cavities, each configured to contain a specific component of the system, and channels to connect the cavities and to house the electrical wiring that connects the components. For example, the cavity 1000 can include a cavity 1092a to house the charge generator, a cavity 1092b to house the rectifier, a cavity 1092c to house the electrical energy storage device, and a cavity 1092d to house the electrical energy access port. The cavities can be configured to provide secure fitting of the respective individual electrical components and can protect the component from damage due to movement or impact of the article of footwear.

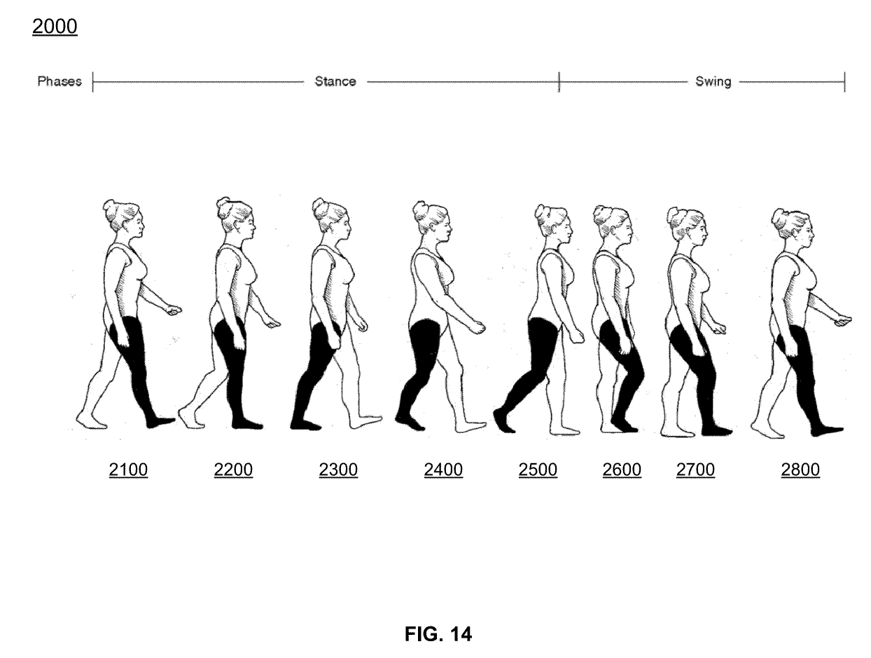

FIG. 14 is a schematic illustration of the human gait cycle. FIG. 14 is presented to show the possible direction(s) of movement of the components of the charge generator during a normal human gait cycle. The ipsilateral foot is denoted in black, and the opposite, or contralateral, foot is denoted in white, in FIG. 14. The gait cycle 2000 is the series of rhythmical, alternating movements of the trunk and limbs which can serve to progress the body along a desired path while maintaining weight-bearing stability, conserving energy, and absorbing the shock of the floor impact. An individual gait cycle 2000 can be defined as occurring between the time at which the heel of one foot touches the ground and the time the same heel touches the ground again. The gait cycle 2000 includes the initial contact (or heel strike) phase 2100, when the heel of the ipsilateral foot touches the ground. During the initial contact 2100 phase, the magnet in the charge generator may move towards the heel of article of footwear worn by user. The next phase in the gait cycle 2000 is the loading response phase 2200, in which the ipsilateral foot comes in full contact with the ground, and the body weight is fully transferred onto the ipsilateral limb to help move the body forward. The magnet may or may not move in the loading response phase 2200, though rotation of the foot about the heel between heel strike (at 2100) and foot flat (at 2200) may move the magnet towards the front of the article of footwear. If the energy harvesting and storage system includes an energy conversion system, the magnet may also be propelled forward by return of stored energy to kinetic energy of the magnet. The next phase is the mid-stance phase 2300, in which the ipsilateral foot is flat on the ground and the weight of the body is directly over the supporting limb. During the mid-stance phase 2300 the contra-lateral foot leaves the ground and the body weight travels along the length of the ipsilateral foot until it is aligned over the forefoot. The magnet would not be expected to move in this phase. The next phase in the gait cycle 2000 is the terminal stance phase 2400 which begins with heel rise of the ipsilateral foot and ends when the contra-lateral (opposite) foot contacts the ground. During the terminal stance phase 2400, the body weight moves ahead of the forefoot and the magnet may move towards the front of the ipsilateral foot. The initial contact 2100, the loading response 2200, the mid-stance 2300, and terminal stance together constitute the stance phase of the gait cycle 2000 which can be defined as the time interval in which the ipsilateral foot is on the ground.

The pre-swing phase 2500 is the next phase in the gait cycle 2000 and begins when the contra-lateral foot contacts the ground and ends with ipsilateral foot toe-off. During this period, the body weight is transferred onto the contra-lateral foot. The components of the charge generator can be expected to stay towards the toes of the foot due to gravitational pull and due to rotation of the foot about the front of the foot (i.e. the heel lifting off of the ground). The initial swing phase 2600 is the next step in the gait cycle 2000 and begins when the ipsilateral foot leaves the ground (toe-off) and ends when the swinging (ipsilateral) foot clears the ground and is opposite the contra-lateral foot (the feet are adjacent to each other). The magnet may stay towards the front of the foot during the initial swing phase 2600. The next phase of the gait cycle 2000, the mid-swing phase 2700, begins following maximum knee flexion and ends when the tibia is in a vertical position (perpendicular to the ground). The magnet may start to move back towards the heel of the foot during the mid-swing phase. The terminal swing phase 2800 is the final phase of the gait cycle 2000 and begins when the tibia passes beyond perpendicular, and the knee fully extends in preparation for initial (heel) contact. In the terminal swing phase 2800, the magnet may move back towards the heel of the foot. The pre-swing 2500, the initial swing 2600, the mid-swing 2700, and the terminal swing 2800 together can constitute the swing phase of the gait cycle 2000 which can be defined as the time interval in which the ipsilateral foot is swinging and not on the ground. During the swing phase the contra-lateral foot has total responsibility for supporting body weight while the ipsilateral foot is in swing.

While various embodiments have been described above, it should be understood that they have been presented by way of example only, and not limitation. Where methods described above indicate certain events occurring in certain order, the ordering of certain events may be modified. Additionally, certain of the events may be performed concurrently in a parallel process when possible, as well as performed sequentially as described above.

What is claimed is:

1. An apparatus comprising:
an article of footwear;
a charge generator mounted to the article of footwear and including:
a conductive coil;
a magnet disposed for movement relative to the coil in response to movement of the article of footwear to generate an electrical potential in the coil;
a electrical energy storage device mounted to the article of footwear and operatively coupled to the charge generator; and
an electrical energy access port operatively coupled to the electrical energy storage device.

2. The apparatus of claim 1, wherein:
the article of footwear includes a sole; and
the magnet is disposed for movement relative to the coil in response to movement of the article of footwear in a direction approximately parallel to the sole of the article of footwear.

3. The apparatus of claim 1, wherein:
the article of footwear includes a sole having a longitudinal axis; and
the magnet is disposed for movement relative to the coil in response to movement of the article of footwear in a direction approximately parallel to the longitudinal axis of the sole of the article of footwear.

4. The apparatus of claim 1, wherein the electrical energy storage device is one of a battery or a capacitor.

5. The apparatus of claim 1, wherein the article of footwear has a sole including a heel portion and the charge generator is mounted to the heel portion of the sole.

6. The apparatus of claim 1, wherein the article of footwear has a sole including a front portion and the electrical energy storage device is mounted to the front portion of the sole.

7. The apparatus of claim 1, wherein the electrical energy access port is mounted to the article of footwear and configured to be accessible from the exterior of the article of footwear.

8. The apparatus of claim 1, wherein the electrical energy access port is one of a computer port and a household electrical outlet.

9. The apparatus of claim 1, wherein the electrical energy access port is configured to transmit energy wirelessly.

10. The apparatus of claim 1, further comprising a water resistant enclosure containing one or more of the electrical energy storage device, the electrical energy access port, or the charge generator.

11. The apparatus of claim 1:
wherein the magnet is disposed for movement relative to the conductive coil in each of a first direction and a second, opposite direction, movement in the first direction generating an electrical potential of a first polarity, movement in the second direction generating an electrical potential of a second, opposite polarity, and
further comprising a rectifier configured to receive current from the coil at the first polarity and the second polarity, and to output current of a single polarity to the electrical charge storage device.

12. The apparatus of claim 1, further comprising a signal generating device coupled to the electrical charge storage device to receive operating electrical energy from the electrical charge storage device.

13. The apparatus of claim 12, wherein the signal generating device is one of an accelerometer or a GPS tracking device.

14. The apparatus of claim 1, wherein:
the conductive coil is a first conductive coil, the magnet is a first magnet, and
the charge generator further includes a second conductive coil and a second magnet disposed for movement relative to the second coil in response to movement of the article of footwear to generate an electrical potential in the second coil.

15. The apparatus of claim 1 wherein the charge generator further includes an energy converter disposed in operative relationship with the magnet to convert kinetic energy of the magnet to potential energy and to convert the potential energy back to kinetic energy.

16. The apparatus of claim 15 wherein the energy converter is a resilient member.

17. The apparatus of claim 16 wherein the resilient member is a coil spring.

18. The apparatus of claim 15 wherein:
the magnet is a first magnet having a polarity; and
the energy converter includes a second magnet having a polarity, the second magnet being disposed and oriented so that the polarity of the second magnet is opposite to that of the first magnet.

19. The apparatus of claim 1 wherein:
the conductive coil is disposed about a volume, the magnet is disposed within the volume for movement therein relative to the conductive coil, and
the volume is substantially fluidically isolated from the environment, and is substantially evacuated.

20. The apparatus of claim 11, further comprising an amplifier coupled to the rectifier to modulate the current from the rectifier.

21. The apparatus of claim 1, further comprising a power conditioner coupled to the electrical energy access port and to the electrical energy storage device and configured to receive electrical energy from an external source coupleable to the electrical energy access port and to provide electrical energy to the electrical energy storage device.

22. The apparatus of claim 1, wherein the conductive coil is configured as one of a cylinder or a torus.

23. An apparatus comprising:
a charge generator including:
a conductive coil;
a magnet disposed for movement relative to the coil to generate an electrical potential in the coil;
a electrical energy storage device coupleable to the charge generator; and
an electrical energy access port coupleable to the electrical energy storage device, the charger generator, electrical energy storage device, and electrical energy access port configured to be mounted to an article of footwear so that the charge generator is operable to generate an electrical potential in response to movement of the article of footwear.

24. The apparatus of claim 23, wherein the charge generator is configured to be mounted to the article of footwear such that movement of the article of footwear produces movement of the magnet relative to the conductive coil.

25. The apparatus of claim 23, wherein:
the conductive coil is a first conductive coil,
the magnet is a first magnet, and
the charge generator further includes a second conductive coil and a second magnet disposed for movement relative to the second coil in response to movement of the article of footwear to generate an electrical potential in the second coil.

26. The apparatus of claim 23, wherein the electrical energy storage device is one of a battery or a capacitor.

27. The apparatus of claim 23, wherein the charge generator can be configured to be mounted to the heel portion of the sole of an article of footwear.

28. The apparatus of claim 23, wherein the electrical energy storage device can be configured to be mounted to the front portion of the sole of an article of footwear.

29. The apparatus of claim 23, wherein the electrical energy access port is configured to be mounted to the article of footwear such that the electrical energy access port is accessible from the exterior of the article of footwear.

30. The apparatus of claim 23, wherein the electrical energy access port is one of a computer port and a household electrical outlet.

31. The apparatus of claim 23, wherein the electrical energy access port is configured to transmit energy wirelessly.

32. The apparatus of claim 23, further comprising a water resistant enclosure configured to be coupled to the article of footwear and to contain one or more of the electrical energy storage device, the electrical energy access port, or the charge generator.

33. The apparatus of claim 23:
wherein the magnet is disposed for movement relative to the conductive coil in each of a first direction and a second, opposite direction, movement in the first direction generating an electrical potential of a first polarity, movement in the second direction generating an electrical potential of a second, opposite polarity, and
further comprising a rectifier configured to receive current from the coil at the first polarity and the second polarity, and to output current of a single polarity to the electrical charge storage device.

34. The apparatus of claim 23 wherein the charge generator further includes an energy converter disposed in operative relationship with the magnet to convert kinetic energy of the magnet to potential energy and to convert the potential energy back to kinetic energy.

35. The apparatus of claim 34 wherein the energy converter is a resilient member.

36. The apparatus of claim 35 wherein the resilient member is a coil spring.

37. The apparatus of claim 34 wherein:
the magnet is a first magnet having a polarity; and
the energy converter includes a second magnet having a polarity, the second magnet being disposed and oriented so that the polarity of the second magnet is opposite to that of the first magnet.

38. The apparatus of claim 23 wherein:
the conductive coil is disposed about a volume, the magnet is disposed within the volume for movement therein relative to the conductive coil, and
the volume is substantially fluidically isolated from the environment, and is substantially evacuated.

39. The apparatus of claim 33, further comprising an amplifier coupled to the rectifier to modulate the current from the rectifier.

40. The apparatus of claim 23, further comprising a signal transmitter coupled to the electrical charge storage device to receive operating electrical energy from the electrical charge storage device.

41. The apparatus of claim 23, further comprising a power conditioner coupled to the electrical energy access port and to the electrical energy storage device and configured to receive electrical energy from an external source coupleable to the electrical energy access port and to provide electrical energy to the electrical energy storage device.

42. The apparatus of claim 23, further comprising instructions for mounting the apparatus inside an article of footwear.

43. A method comprising:
causing movement of an article of footwear having mounted thereto:
a charge generator configured to generate an electrical potential in response to movement of the article of footwear;
a electrical energy storage device operatively coupled to the charge generator; and
an electrical energy access port operatively coupled to the electrical energy storage device;
thereby causing the charge generator to charge the electrical energy storage device;
coupling to the electrical energy access port an electronic charge-consuming device, thereby causing the electrical energy storage device to provide charge to the electronic charge-consuming device.

44. The method of claim 43, further comprising coupling to the electrical energy access port an electronic charge-providing device, thereby causing the electrical energy storage device to receive charge from the electronic charge-providing device.

45. A method comprising:
mounting inside an article of footwear:
a charge generator;
an electrical energy storage device; and
an electrical energy access port.

46. The method of 45, wherein:
the article of footwear includes a sole having a heel portion; and
the mounting includes mounting the charge generator to the heel portion of the sole.

47. The method of 45, wherein:
the article of footwear includes a sole having a front portion; and
the mounting includes mounting the electrical energy storage device to the front portion of the sole.

48. The method of claim 45, further comprising one or more of electrically coupling the charge generator to the electrical energy storage device, or electrically coupling the electrical energy storage device to the electrical energy access port.

49. The method of claim 45, further comprising forming in the article of footwear a cavity sized to receive one or more of the charge generator, the electrical energy storage device, and the electrical energy access port.
